(19) United States
(12) Patent Application Publication
(10) Pub. No.: US 2026/0297469 A1
(43) Pub. Date: Oct. 1, 2026

(54) CLEANING COMPOSITION AND METHOD OF FORMING PHOTORESIST PATTERN USING THE SAME

(71) Applicant: DONGWOO FINE-CHEM CO., LTD., Jeonbuk-do (KR)

(72) Inventors: BAEK HYUN CHO, Jeonbuk-do (KR); GI JIN KWUN, Jeonbuk-do (KR); HYUNG SUB CHOI, Jeonbuk-do (KR)

(21) Appl. No.: 19/576,316

(22) Filed: Mar. 24, 2026

(30) Foreign Application Priority Data
Mar. 25, 2025 (KR) 10-2025-0038341

(51) Int. Cl. C11D 7/50; C11D 7/26; C11D 7/32; G03F 7/42

(52) U.S. Cl. CPC C11D 7/5022; C11D 7/261; C11D 7/3209; C11D 7/3218; G03F 7/425; C11D 2111/22

(57) ABSTRACT

A cleaning composition includes an alcohol-based solvent including a non-cyclic alcohol, and a time-lapse stabilizer including an amine compound or a cyclic alcohol. A content of the time-lapse stabilizer is greater than 0, and 1 ppb or less based on a total weight of the composition. The cleaning composition has improved time-lapse stability, and an amount of impurities may be suppressed or controlled even after long-term storage of the composition.

### CROSS-REFERENCE TO RELATED APPLICATION AND CLAIM OF PRIORITY

This application claims priority to Korean Patent Application No. 10-2025-0038341 filed on Mar. 25, 2025, the entire disclosures of which are incorporated by reference herein.

### BACKGROUND

### 1. Field

The present invention relates to a cleaning composition and a method for forming a photoresist pattern using the same.

### 2. Description of the Related Art

A composition containing an alcohol-based solvent can be used for cleaning an electronic device such as a semiconductor device or may be used for removing photoresist residues during a photo-lithography process in a semiconductor device manufacture process.

For example, a photoresist composition may be applied to a semiconductor substrate, and then soft-baked to form a photoresist layer. Subsequently, the photoresist layer may be partially removed by exposure and development processes to form a photoresist pattern. An etching process using the photoresist pattern as an etching mask may be performed to form wirings, electrodes, insulating patterns, or the like, of the semiconductor device.

As described above, the photoresist pattern may be formed by the exposure and development processes, and then the photoresist residues on the semiconductor substrate may be removed using a cleaning solution.

However, if impurities are present in the cleaning solution, the impurities may remain on a surface of the semiconductor device to cause defects. The impurities may be incorporated into the cleaning solution during a preparation process or may be formed by a side reaction during storage. Thus, management of an amount of impurities may be needed when storing the cleaning solution for a long period.

### SUMMARY

According to an aspect of the present invention, there is provided a cleaning composition providing improved stability over time change and pattern reliability.

According to an aspect of the present invention, there is provided a method of forming a photoresist pattern using the cleaning composition.
(1) A cleaning composition, including: an alcohol-based solvent including a non-cyclic alcohol; and a time-lapse stabilizer including an amine compound or a cyclic alcohol, wherein a content of the time-lapse stabilizer is greater than 0, and 1 ppb or less based on a total weight of the composition.
(2) The cleaning composition of the above (1), wherein a content of the time-lapse stabilizer is in a range from 0.1 ppt to 1 ppb based on the total weight of the composition.
(3) The cleaning composition of the above (1), wherein the time-lapse stabilizer includes the amine compound or the cyclic alcohol which have 2 to 10 carbon atoms.
(4) The cleaning composition of the above (1), wherein the time-lapse stabilizer includes at least one selected from the group consisting of ethylamine, aniline, ethanolamine, 1-phenylethanol and cyclohexanol.
(5) The cleaning composition of the above (1), wherein the alcohol-based solvent includes the non-cyclic alcohol having 2 to 5 carbon atoms.
(6) The cleaning composition of the above (1), wherein the alcohol-based solvent includes at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol and 2,2-dimethyl-1-propanol.
(7) The cleaning composition according to the above (1), wherein the alcohol-based solvent includes 2-propanol.
(8) The cleaning composition of the above (7), wherein the alcohol-based solvent further includes at least one selected from the group consisting of ethanol, 1-propanol, 1-butanol and 1-pentanol.
(9) The cleaning composition of the above (1), wherein a boiling point of the alcohol-based solvent is 110° C. or less, and a vapor pressure of the alcohol-based solvent at 25° C. is 0.5 kPa or higher.
(10) The cleaning composition of the above (1), wherein a content of the alcohol-based solvent is 99 wt % or more, and less than 100 wt % based on the total weight of the composition.
(11) The cleaning composition of the above (1), wherein the composition satisfies Formula 1:

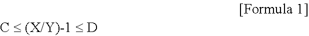

wherein, in Formula 1, X represents a total content of an aldehyde-based compound and a ketone-based compound based on the total weight of the composition, measured after a storage of the composition at 60° C. for 90 days, Y represents a total content of the aldehyde-based compound and the ketone-based compound based on the total weight of the composition, measured before the storage, and C is greater than 0 and 0.05 or less, and D is in a range from 0.07 and 0.2.
(12) A method of forming a photoresist pattern, including: forming a photoresist layer on a substrate; partially removing the photoresist layer to form a photoresist pattern; and cleaning the substrate on which the photoresist pattern is formed using the above-describe cleaning composition.
(13) The method of the above (12), further including washing the substrate on which the photoresist pattern is formed with water prior to the cleaning using the cleaning composition.

Photoresist residues generated after a development process may be effectively removed using a cleaning composition according to embodiments of the present invention. Further, damages to the photoresist pattern during a cleaning process may be prevented to achieve a uniform pattern profile.

In example embodiments, the cleaning composition may include a time-lapse stabilizer including an amine compound or a cyclic alcohol so that an amount of impurities generated in the cleaning composition may be controlled or suppressed

Accordingly, a high-resolution target pattern having desired pattern spacing and size may be stably formed by a photo-lithography process using the photoresist pattern even when the cleaning composition is used after a long-term storage.

### BRIEF DESCRIPTION OF THE DRAWINGS

FIGS. 1 to 4 are schematic cross-sectional views illustrating a method of forming a pattern in accordance with example embodiments.

### DETAILED DESCRIPTION OF THE EMBODIMENTS

Embodiments of the present invention provide a cleaning composition including an alcohol-based solvent and a time-lapse stabilizer. Further, a method of forming a photoresist pattern using the cleaning composition is provided.

The term “ppb” used herein refers to “parts-per-billion (10⁻⁹)” and “ppt” used herein refers to “parts-per-trillion (10⁻¹²)”, and the ppb and ppt may refer to a weight-based content.

Hereinafter, embodiments of the present invention will be described in detail.

### <Cleaning Composition>

A cleaning composition (hereinafter, that may be abbreviated as a composition) according to example embodiments may include an alcohol-based solvent and a time-lapse stabilizer.

The alcohol-based solvent may remove process residues such as an undeveloped photoresist or a residual developer present on a semiconductor substrate. For example, organic and inorganic residues present between photoresist patterns after exposure and development processes may be effectively removed from the semiconductor substrate using the alcohol-based solvent included in the cleaning composition.

In some embodiments, the alcohol-based solvent may include a non-cyclic alcohol. In a preferable embodiment, the alcohol-based solvent may include a non-cyclic alcohol having 2 to 5 carbon atoms.

For example, the alcohol-based solvent may include ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol, 2,2-dimethyl-1-propanol, or the like. These may be used alone or in a combination of two or more therefrom.

For example, methanol has a high volatility to have low cleaning capability and stability. An alcohol having more than 5 carbon atoms may remain on a surface of a semiconductor substrate after cleaning. Thus, when the alcohol-based solvent includes an alcohol having 2 to 5 carbon atoms, defects during a semiconductor device fabrication may be reduced.

In example embodiments, the alcohol-based solvent may be obtained by refining a crude material. A purity of the alcohol-based solvent may be improved by the refining process.

For example, 2-propanol derived from a fossil resource such as coal, oil, natural gas, etc., as a raw material before the refinement may be used as the alcohol-based solvent, and 2-propanol (Bio-2-propanol) derived from a biomass may be used.

Examples of Bio-2-propanol include 2-propanol obtained using bacteria capable of producing 2-propanol from a biomass material (see International Patent Publication No. 2009/008377), 2-propanol obtained by hydrating propylene obtained using a biomethanol, 2-propanol obtained by reducing acetone obtained using bioethanol, 2-propanol obtained by hydrating propylene obtained using bioethanol, or the like.

In some embodiments, the alcohol-based solvent may include a secondary alcohol. Examples of the secondary alcohol include 2-propanol, 2-butanol, 2-pentanol, 3-pentanol, or 3-methyl-2-butanol, preferably may include 2-propanol.

In some embodiments, the alcohol-based solvent may include at least one selected from the group consisting of ethanol, 1-propanol, 2-propanol, 1-butanol and 1-pentanol.

In some embodiments, the alcohol-based solvent may include 2-propanol, and an alcohol-based solvent different from 2-propanol. For example, the alcohol-based solvent may include 2-propanol, and ethanol, 1-propanol, 1-butanol and/or 1-pentanol.

For example, the alcohol having 2 or 3 carbon atoms have a low boiling point, and thus may not remain on a surface of a semiconductor substrate after a cleaning process. Accordingly. a production yield of a semiconductor device may be increased.

In some embodiments, the alcohol-based solvent may include an alcohol having a boiling point of 110° C. or lower. For example, the alcohol having a boiling point of 110° C. or lower may include ethanol, 1-propanol, 2-propanol, 2-butanol, isobutanol, tert-butanol, tert-amyl alcohol, or the like.

For example, the alcohol having a boiling point of 110° C. or lower may be vaporized at a lower temperature, and thus may not remain on the surface of the semiconductor substrate after the cleaning process.

In some embodiments, a vapor pressure of the alcohol-based solvent at 25° C. may be 0.5 kPa or higher. For example, the alcohol having a vapor pressure of 0.5 kPa or higher at 25° C. may include ethanol, 1-propanol, 2-propanol, 1-butanol, 2-butanol, isobutanol, tert-butanol, 2-pentanol, 3-pentanol, tert-amyl alcohol, 2,2-dimethyl-1-propanol, or the like. These may be used alone or in a combination of two or more therefrom.

For example, the alcohol having a vapor pressure of 0.5 kPa or higher at 25° C. may be vaporized more easily, and may not remain on the surface of the semiconductor substrate after the cleaning process.

In example embodiments, a content of the alcohol-based solvent based on a total weight of the composition may be 99 wt % or more, and less than 100 wt %. In some embodiments, the content of the alcohol-based solvent based on the total weight of the composition may be 99.9 wt % or more and less than 100 wt %, 99.95 wt % or more and less than 100 wt %, or 99.99 wt % or more and less than 100 wt %.

In some embodiments, a content of 2-propanol based on the total weight of the composition may be 99 wt % or more, and less than 100 wt %. In an embodiment, the content of 2-propanol based on the total weight of the composition may be 99.9 wt % or more and less than 100 wt %, 99.95 wt % or more and less than 100 wt %, or 99.99 wt % or more and less than 100 wt %.

In some embodiments, the cleaning composition may include an alcohol-based solvent different from 2-propanol, as a remainder excluding the content of 2-propanol and the time-lapse stabilizer. For example, the cleaning composition may include the time-lapse stabilizer in an amount described below and 2-propanol in the amount described above, and may include the alcohol-based solvent different from the 2-propanol in a remaining amount.

The term “remainder or remaining amount” as used herein refers to a variable amount that may be changed depending on an addition of another component. For example, the cleaning composition may further include an organic solvent other than the alcohol-based solvent within a range in which the action of the alcohol-based solvent and the time-lapse stabilizer may not be hindered.

According to embodiments of the present disclosure, an additional amine compound may not be included except for the time-lapse stabilizer in the amount described below. For example, the cleaning composition may not include an amine compound as an organic solvent. In some embodiments, the organic solvent of the cleaning composition may substantially consist of the alcohol-based solvent.

The cleaning composition may include the time-lapse stabilizer. In example embodiments, the time-lapse stabilizer may include an amine compound and/or a cyclic alcohol.

The amine compound may include an aliphatic amine or an aromatic amine.

The cyclic alcohol may refer to an alcohol compound containing an alicyclic ring or an aromatic ring in a molecule. The cyclic alcohol may include an alicyclic alcohol or an aromatic alcohol.

In example embodiments, the time-lapse stabilizer may include an amine compound and/or a cyclic alcohol having 2 to 10 carbon atoms, preferably 2 to 8 carbon atoms. In the above carbon number range, an impurity conversion reaction described below may be accelerated. For example, if the carbon number of the time-lapse stabilizer increases excessively, the impurity conversion reaction may be inhibited due to a steric hindrance.

Non-limiting examples of the time-lapse stabilizer include ethylamine, aniline, ethanolamine, 1-phenylethanol, cyclohexanol, or the like. These may be used alone or in a combination of two or more therefrom.

The above-mentioned time-lapse stabilizer may convert impurities contained in the alcohol-based solvent (e.g., 2-propanol) into the alcohol-based solvent through the impurity conversion reaction according to conversion schemes below.

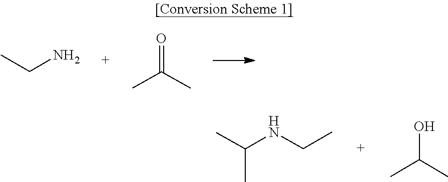

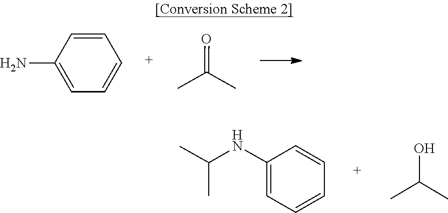

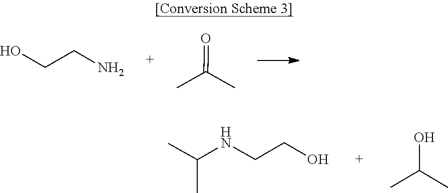

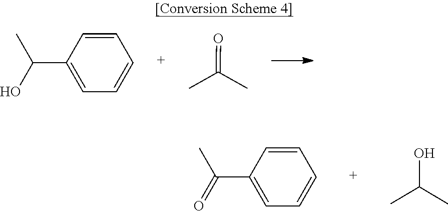

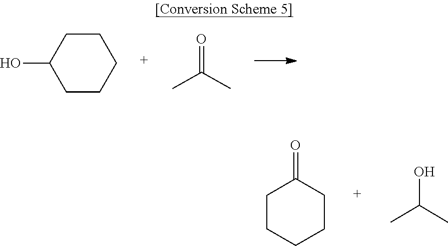

The impurities such as a ketone (e.g., acetone) or an aldehyde (e.g., acetaldehyde) may be included as byproducts during a preparation process of the alcohol-based solvent (e.g., hydration of propylene). Further, the ketone or aldehyde impurities may be continuously generated by a self-reaction during storage of the alcohol-based solvent.

Accordingly, the impurities may degrade purity of the cleaning composition and may also degrade reliability of the cleaning process using the cleaning composition.

However, according to embodiments of the present invention, an amount of acetone/acetaldehyde may be reduced or controlled by the time-lapse stabilizer through the above-described conversion scheme. For example, the amount of acetone/acetaldehyde generated during long-term storage of the cleaning composition may be suppressed or controlled by the time-lapse stabilizer.

Thus, a target purity for a practical use in an actual process may be maintained for an extended period while enhancing time-lapse stability and reliability of the cleaning composition.

In example embodiments, a content of the time-lapse stabilizer may be greater than 0, and 1 ppb or less based on the total weight of the cleaning composition. If the content of the time-lapse stabilizer exceeds 1 ppb, an amount of impurities may be increased due to the time-lapse stabilizer.

Preferably, the content of the time-lapse stabilizer may be in a range from 0.1 ppt to 1 ppb, from 0.1 ppt to 0.5 ppb, or from 0.1 ppt to 10 ppt, based on the total weight of the cleaning composition.

In the above content range, the time-lapse stabilizer may effectively suppress/manage impurities without lowering solubility of photoresist residues by the cleaning composition.

In example embodiments, the cleaning composition may satisfy Formula 1.

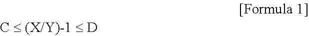

In Formula 1, X represents a total content of an aldehyde-based compound and a ketone-based compound based on the total weight of the cleaning composition, measured after storing the composition at 60° C. for 90 days, and Y represents a total content of the aldehyde-based compound and the ketone-based compound based on the total weight of the composition, measured before the storage.

In Formula 1, C may be greater than 0 and 0.05 or less, and D may be in a range from 0.07 and 0.2.

A change ratio in the content of the aldehyde-based compound and the ketone-based compound before and after the high-temperature storage of the composition may be, e.g., 20% or less, 15% or less, 10% or less, or 7% or less.

The change ratio in the content of the aldehyde-based compound and the ketone-based compound before and after the high-temperature storage of the composition may be, e.g., greater than 0, 1% or more, 2% or more, or 3% or more.

For example, in Equation 1, D may be 0.2, 0.15, 0.1, 0.08, or 0.07, and C may be 0.01, 0.02, or 0.03.

In the above range, the cleaning composition may provide improved time-lapse stability and enhanced long-term storage stability.

The aldehyde-based compound and the ketone-based compound may be trace impurities formed by a natural oxidation of the alcohol-based solvent. The composition may have improved time-lapse stability, and thus increase in impurities including the aldehyde-based compound and the ketone-based compound may be suppressed even when being stored for an extended period.

In an embodiment, in Formula 1, X and Y are greater than 0, X may be 2600 ppb or less, 2500 ppb or less, 2400 ppb or less, or 2300 ppb or less, and Y may be 2300 ppb or less or 2200 ppb or less.

### <Method of Forming Photoresist Pattern>

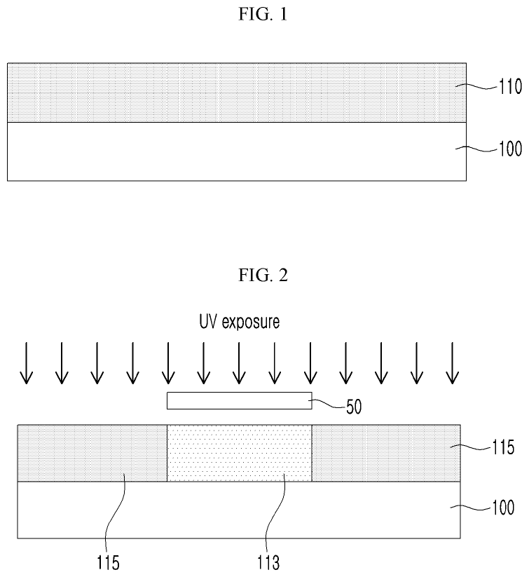

FIGS. 1 to 4 are schematic cross-sectional views for describing a method of forming a pattern according to embodiments. For example, in FIGS. 1 to 4, a method of forming a pattern using a negative photoresist is provided.

However, the cleaning composition according to embodiments is not limited to the processes of FIGS. 1 to 4, and may also be used in a pattern formation process using a positive photoresist.

Referring to FIG. 1, a photoresist layer 110 may be formed by coating a photoresist material on a substrate 100.

The substrate 100 may include a semiconductor material such as single crystal silicon or single crystal germanium. The substrate 100 may be formed to include polysilicon.

In some embodiments, a soft baking process may be performed after forming the photoresist layer 110. Accordingly, an organic solvent included in the photoresist layer 110 may be evaporated.

Referring to FIG. 2, a non-exposed portion 113 and an exposed portion 115 may be formed on the substrate 100 by an exposure process. The exposure process may be performed using a light source (e.g., a UV light source such as an EUV light source, a KrF laser, etc.) and an exposure mask 50.

Light passing through the exposure mask 50 may be irradiated to the photoresist layer 110. Accordingly, the photoresist layer 110 may have the non-exposed portion 113 and the exposed portion 115.

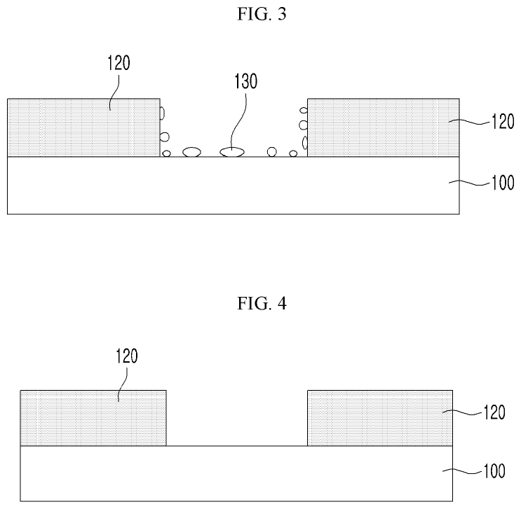

Referring to FIG. 3, a photoresist pattern 120 may be formed on the substrate 100 by a developing process. For example, the non-exposed portion 113 may be removed from the substrate 100 using a developer solution to form the photoresist pattern 120 including the exposed portion 115. The developer solution may be an aqueous tetramethylammonium hydroxide (TMAH) solution.

FIG. 3 illustrates a pattern formation process using a negative photoresist, but the pattern formation is not limited thereto. For example, the pattern formation process may be performed using a positive photoresist. In this case, the exposed portion 115 may be removed, and a photoresist pattern may be formed from the non-exposed portion 113.

In some embodiments, a post-baking process may be further performed after the exposure process or after the development process.

A developing residue 130 may be present on the substrate 100 after the developing process. The developing residue 130 may be an undeveloped photoresist or a developing solution residue. When the developing residue 130 remains on the substrate 100 or the photoresist pattern 120, defects may occur during a fabrication of a semiconductor device.

Referring to FIG. 4, the above-described cleaning composition according to embodiments may be applied or immersed on the substrate 100. Accordingly, the developing residue 130 formed on the substrate 100 or the photoresist pattern 120 may be removed.

The cleaning process may be performed by applying the cleaning composition according to the above-described embodiments described to the substrate 100 under commonly known cleaning conditions.

In some embodiments, a cleaning temperature may be in a range from 25° C. to 70° C., preferably from 25° C. to 50° C. A residence time of the substrate 100 when immersed in the cleaning composition may be in a range from about 5 seconds to 10 minutes, preferably from 10 seconds to 5 minutes.

In some embodiments, in the cleaning process, a first cleaning (washing) of removing the developing residue using deionized water may be performed, and then a second cleaning using the cleaning composition according to the above-described embodiments may be performed.

As described above, the cleaning composition includes the alcohol-based solvent and the time-lapse stabilizer, so that the developing residue 130 may be removed with stable time-lapse properties even when the composition is used after a long-term storage. Accordingly, resolution and reliability of the photo-lithography process using the photoresist pattern 120 may be improved, and a target pattern with a fine line width may be obtained.

In addition to the pattern formation process using a photoresist, the cleaning composition according to embodiments may be used for cleaning an electronic device such as a semiconductor or a display, and may also be used for manufacturing various devices (an electric device such as a touch sensor, a display device, etc.) in which the cleaning process is performed.

Hereinafter, preferred embodiments are provided to help understanding of the present invention, but these embodiments are merely illustrative of the present invention and do not limit the scope of the attached patent claims, and it is obvious to those skilled in the art that various changes and modifications to the embodiments are possible within the scope of the present invention. These modifications are to be interpreted as being within the scope of the attached claims.

### Examples and Comparative Examples

The cleaning compositions of Examples and Comparative Examples were prepared by mixing components with corresponding contents shown in Table 1 below. The content of each component is expressed based on a total weight of the cleaning composition. In Table 1, “Re” represents a remainder or a remaining amount.

TABLE 1

| | | | | | alcohol-based | | | | |
|---|---|---|---|---|---|---|---|---|---|
| time-lapse stabilizer | | | | | solvent (wt %) | | | | |
| A1 | A2 | A3 | A4 | A5 | B1 | B2 | B3 | B4 | B5 |

| | | | | | | | |
|---|---|---|---|---|---|---|---|
| Example 1 | 0.1 | ppt | Re | | | | |
| Example 2 | 1 | ppt | Re | | | | |
| Example 3 | 5 | ppt | Re | | | | |
| Example 4 | 10 | ppt | Re | | | | |
| Example 5 | 0.5 | ppb | Re | | | | |
| Example 6 | 1 | ppb | Re | | | | |
| Example 7 | 10 | ppt | 99.99 | Re | | | |
| Example 8 | 10 | ppt | 99.99 | | Re | | |
| Example 9 | 10 | ppt | 99.99 | | | Re | |
| Example 10 | 10 | ppt | 99.99 | | | | Re |

| | | | | | | | |
|---|---|---|---|---|---|---|---|
| Example 11 | 0.1 | ppt | Re | | | | |
| Example 12 | 1 | ppt | Re | | | | |
| Example 13 | 5 | ppt | Re | | | | |
| Example 14 | 10 | ppt | Re | | | | |
| Example 15 | 0.5 | ppb | Re | | | | |
| Example 16 | 1 | ppb | Re | | | | |
| Example 17 | 10 | ppt | 99.99 | Re | | | |
| Example 18 | 10 | ppt | 99.99 | | Re | | |
| Example 19 | 10 | ppt | 99.99 | | | Re | |
| Example 20 | 10 | ppt | 99.99 | | | | Re |

| | | | | | | | |
|---|---|---|---|---|---|---|---|
| Example 21 | 0.1 | ppt | Re | | | | |
| Example 22 | 1 | ppt | Re | | | | |
| Example 23 | 5 | ppt | Re | | | | |
| Example 24 | 10 | ppt | Re | | | | |
| Example 25 | 0.5 | ppb | Re | | | | |
| Example 26 | 1 | ppb | Re | | | | |
| Example 27 | 10 | ppt | 99.99 | Re | | | |
| Example 28 | 10 | ppt | 99.99 | | Re | | |
| Example 29 | 10 | ppt | 99.99 | | | Re | |
| Example 30 | 10 | ppt | 99.99 | | | | Re |

| | | | | | | | |
|---|---|---|---|---|---|---|---|
| Example 31 | 0.1 | ppt | Re | | | | |
| Example 32 | 1 | ppt | Re | | | | |
| Example 33 | 5 | ppt | Re | | | | |
| Example 34 | 10 | ppt | Re | | | | |
| Example 35 | 0.5 | ppb | Re | | | | |
| Example 36 | 1 | ppb | Re | | | | |
| Example 37 | 10 | ppt | 99.99 | Re | | | |
| Example 38 | 10 | ppt | 99.99 | | Re | | |
| Example 39 | 10 | ppt | 99.99 | | | Re | |
| Example 40 | 10 | ppt | 99.99 | | | | Re |

| | | | | | | | |
|---|---|---|---|---|---|---|---|
| Example 41 | 0.1 | ppt | Re | | | | |
| Example 42 | 1 | ppt | Re | | | | |
| Example 43 | 5 | ppt | Re | | | | |
| Example 44 | 10 | ppt | Re | | | | |
| Example 45 | 0.5 | ppb | Re | | | | |
| Example 46 | 1 | ppb | Re | | | | |
| Example 47 | 10 | ppt | 99.99 | Re | | | |
| Example 48 | 10 | ppt | 99.99 | | Re | | |
| Example 49 | 10 | ppt | 99.99 | | | Re | |
| Example 50 | 10 | ppt | 99.99 | | | | Re |

| Example 51 | 0.05 | ppt | Re |
|---|---|---|---|
| Comparative | 1.5 | ppb | Re |
| Example 1 | | | |
| Comparative | 2 | ppb | Re |

| Example 2 | | | |
|---|---|---|---|
| Comparative | 2 | ppb | Re |

| Example 3 | | | |
|---|---|---|---|
| Comparative | 2 | ppb | Re |

| Example 4 | | | |
|---|---|---|---|
| Comparative | 2 | ppb | Re |

| Example 5 | | | |
|---|---|---|---|
| Comparative | 2 | ppb | Re |

| | |
|---|---|
| Example 6 | |
| Comparative | 100 |
| Example 7 | |

The components shown in Table 1 are as follows.
A1: ethylamine
A2: aniline
A3: ethanolamine
A4: 1-phenylethanol
A5: cyclohexanol
B1: 2-propanol
B2: 1-propanol
B3: ethanol
B4: 1-butanol
B5: 1-pentanol

### Experimental Example

### (1) Initial Evaluation

A total content (Y) of acetone (C1) and acetaldehyde (C2) in each cleaning composition of Examples and Comparative Examples was measured using an Agilent 7890A/5975C GC-MS instrument and an Agilent CP-Volamine (60 m, 0.32 mm) column.

Specifically, standard materials of acetaldehyde and acetone were prepared, and acetaldehyde and acetone detected in the cleaning compositions of Examples and Comparative Examples were quantitatively analyzed by comparing peak areas of the quantified standard materials.

### (2) Time-Lapse Evaluation

The cleaning compositions of Examples and Comparative Examples were stored at 60° C. for 90 days, and a total content (X) of acetone (C1) and acetaldehyde (C2) was measured using the same method as that in (1).

### (3) Time-lapse Stability Evaluation

A total content change ratio ((X/Y)−1) of acetaldehyde and acetone was calculated, and a time-lapse stability of each cleaning composition of Examples and Comparative Examples was evaluated according to evaluation criteria as follows.
⊚: Content change ratio of 0.1 or less
∘: Content change ratio greater than 0.1 and 0.2 or less
Δ: Content change rate greater than 0.2 and less than 0.3
x: Content change ratio of 0.3 or more

The evaluation results are shown in Table 2 below.

TABLE 2

| | | | | | | | content | time- |
|---|---|---|---|---|---|---|---|---|
| | initial evaluation | | | time-lapse | | | change | lapse |
| | (ppb) | | | evaluation (ppb) | | | ratio | sta- |
| | C1 | C2 | total | C1 | C2 | total | (%) | bility |
| Example 1 | 1150 | 1033 | 2183 | 1211 | 1055 | 2266 | 0.038 | ⊚ |
| Example 2 | 1140 | 1031 | 2171 | 1200 | 1067 | 2267 | 0.044 | ⊚ |
| Example 3 | 1150 | 1047 | 2197 | 1201 | 1092 | 2293 | 0.044 | ⊚ |
| Example 4 | 1133 | 1040 | 2173 | 1208 | 1099 | 2307 | 0.062 | ⊚ |
| Example 5 | 1140 | 1047 | 2187 | 1231 | 1117 | 2348 | 0.074 | ⊚ |
| Example 6 | 1140 | 1034 | 2174 | 1220 | 1133 | 2353 | 0.082 | ⊚ |
| Example 7 | 1150 | 1047 | 2197 | 1200 | 1100 | 2300 | 0.047 | ⊚ |
| Example 8 | 1144 | 1047 | 2191 | 1201 | 1091 | 2292 | 0.046 | ⊚ |
| Example 9 | 1142 | 1047 | 2189 | 1203 | 1090 | 2293 | 0.048 | ⊚ |
| Example 10 | 1150 | 1047 | 2197 | 1203 | 1100 | 2303 | 0.048 | ⊚ |
| Example 11 | 1133 | 1022 | 2155 | 1190 | 1044 | 2234 | 0.037 | ⊚ |
| Example 12 | 1150 | 1047 | 2197 | 1200 | 1089 | 2289 | 0.042 | ⊚ |
| Example 13 | 1157 | 1027 | 2184 | 1210 | 1077 | 2287 | 0.047 | ⊚ |
| Example 14 | 1150 | 1047 | 2197 | 1230 | 1090 | 2320 | 0.056 | ⊚ |
| Example 15 | 1143 | 1033 | 2176 | 1233 | 1110 | 2343 | 0.077 | ⊚ |
| Example 16 | 1150 | 1047 | 2197 | 1230 | 1140 | 2370 | 0.079 | ⊚ |
| Example 17 | 1144 | 1041 | 2185 | 1202 | 1091 | 2293 | 0.049 | ⊚ |
| Example 18 | 1138 | 1047 | 2185 | 1208 | 1080 | 2288 | 0.047 | ⊚ |
| Example 19 | 1150 | 1032 | 2182 | 1201 | 1088 | 2289 | 0.049 | ⊚ |
| Example 20 | 1137 | 1040 | 2177 | 1200 | 1090 | 2290 | 0.052 | ⊚ |
| Example 21 | 1153 | 1047 | 2200 | 1200 | 1077 | 2277 | 0.035 | ⊚ |
| Example 22 | 1140 | 1047 | 2187 | 1199 | 1080 | 2279 | 0.042 | ⊚ |
| Example 23 | 1135 | 1044 | 2179 | 1199 | 1081 | 2280 | 0.046 | ⊚ |
| Example 24 | 1150 | 1047 | 2197 | 1211 | 1103 | 2314 | 0.053 | ⊚ |
| Example 25 | 1140 | 1047 | 2187 | 1229 | 1111 | 2340 | 0.070 | ⊚ |
| Example 26 | 1140 | 1047 | 2187 | 1266 | 1100 | 2366 | 0.082 | ⊚ |
| Example 27 | 1150 | 1047 | 2197 | 1207 | 1097 | 2304 | 0.049 | ⊚ |
| Example 28 | 1144 | 1041 | 2185 | 1200 | 1100 | 2300 | 0.053 | ⊚ |
| Example 29 | 1142 | 1038 | 2180 | 1204 | 1096 | 2300 | 0.055 | ⊚ |
| Example 30 | 1146 | 1040 | 2186 | 1214 | 1100 | 2314 | 0.059 | ⊚ |
| Example 31 | 1133 | 1020 | 2153 | 1170 | 1066 | 2236 | 0.039 | ⊚ |
| Example 32 | 1144 | 1047 | 2191 | 1200 | 1089 | 2289 | 0.045 | ⊚ |
| Example 33 | 1150 | 1027 | 2177 | 1202 | 1080 | 2282 | 0.048 | ⊚ |
| Example 34 | 1141 | 1022 | 2163 | 1215 | 1077 | 2292 | 0.060 | ⊚ |
| Example 35 | 1150 | 1033 | 2183 | 1233 | 1111 | 2344 | 0.074 | ⊚ |
| Example 36 | 1139 | 1040 | 2179 | 1240 | 1120 | 2360 | 0.083 | ⊚ |
| Example 37 | 1144 | 1041 | 2185 | 1200 | 1100 | 2300 | 0.053 | ⊚ |
| Example 38 | 1150 | 1033 | 2183 | 1213 | 1099 | 2312 | 0.059 | ⊚ |
| Example 39 | 1139 | 1032 | 2171 | 1200 | 1100 | 2300 | 0.059 | ⊚ |
| Example 40 | 1137 | 1040 | 2177 | 1199 | 1103 | 2302 | 0.057 | ⊚ |
| Example 41 | 1133 | 1022 | 2155 | 1170 | 1059 | 2229 | 0.034 | ⊚ |
| Example 42 | 1150 | 1047 | 2197 | 1200 | 1092 | 2292 | 0.043 | ⊚ |
| Example 43 | 1157 | 1033 | 2190 | 1222 | 1080 | 2302 | 0.051 | ⊚ |
| Example 44 | 1141 | 1033 | 2174 | 1230 | 1077 | 2307 | 0.061 | ⊚ |
| Example 45 | 1150 | 1033 | 2183 | 1227 | 1111 | 2338 | 0.071 | ⊚ |
| Example 46 | 1139 | 1040 | 2179 | 1235 | 1144 | 2379 | 0.092 | ⊚ |
| Example 47 | 1150 | 1033 | 2183 | 1211 | 1099 | 2310 | 0.058 | ⊚ |
| Example 48 | 1150 | 1033 | 2183 | 1208 | 1090 | 2298 | 0.053 | ⊚ |
| Example 49 | 1139 | 1032 | 2171 | 1207 | 1090 | 2297 | 0.058 | ⊚ |
| Example 50 | 1137 | 1033 | 2170 | 1201 | 1101 | 2302 | 0.061 | ⊚ |
| Example 51 | 1110 | 1050 | 2160 | 1270 | 1120 | 2390 | 0.106 | ◯ |
| Comparative | 1145 | 1050 | 2195 | 1405 | 1260 | 2665 | 0.214 | Δ |
| Example 1 | | | | | | | | |
| Comparative | 1139 | 1044 | 2183 | 1401 | 1266 | 2667 | 0.222 | Δ |
| Example 2 | | | | | | | | |
| Comparative | 1133 | 1032 | 2165 | 1370 | 1277 | 2647 | 0.223 | Δ |
| Example 3 | | | | | | | | |
| Comparative | 1140 | 1027 | 2167 | 1368 | 1271 | 2639 | 0.218 | Δ |
| Example 4 | | | | | | | | |
| Comparative | 1139 | 1022 | 2161 | 1408 | 1280 | 2688 | 0.244 | Δ |
| Example 5 | | | | | | | | |
| Comparative | 1139 | 1029 | 2168 | 1408 | 1277 | 2685 | 0.238 | Δ |
| Example 6 | | | | | | | | |
| Comparative | 1150 | 1041 | 2191 | 1799 | 1571 | 3370 | 0.538 | X |
| Example 7 | | | | | | | | |

Referring to Table 2, in the cleaning compositions of Examples containing the time-lapse stabilizer, the content change ratio of aldehyde and ketone compounds was suppressed even when the compositions were exposed to high temperature for a long period.

In Comparative Example 7 where the time-lapse stabilizer was not included, the time-lapse stability was significantly degraded. In Comparative Examples 1 to 6 where the content of the time-lapse stabilizer was excessively increased, the time-lapse stability was degraded compared those from Examples.

Referring to Example 51, the content of the time-lapse stabilizer was slightly reduced, and the impurity content change ratio was increased compared to those from other Examples

What is claimed is:

1. A cleaning composition comprising:
an alcohol-based solvent comprising a non-cyclic alcohol; and
a time-lapse stabilizer comprising an amine compound or a cyclic alcohol,
wherein a content of the time-lapse stabilizer is greater than 0, and 1 ppb or less based on a total weight of the composition.

2. The cleaning composition of claim 1, wherein a content of the time-lapse stabilizer is in a range from 0.1 ppt to 1 ppb based on the total weight of the composition.

3. The cleaning composition of claim 1, wherein the time-lapse stabilizer comprises the amine compound or the cyclic alcohol which have 2 to 10 carbon atoms.

4. The cleaning composition of claim 1, wherein the time-lapse stabilizer comprises at least one selected from the group consisting of ethylamine, aniline, ethanolamine, 1-phenylethanol and cyclohexanol.

5. The cleaning composition of claim 1, wherein the alcohol-based solvent comprises the non-cyclic alcohol having 2 to 5 carbon atoms.

6. The cleaning composition of claim 1, wherein the alcohol-based solvent comprises at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol and 2,2-dimethyl-1-propanol.

7. The cleaning composition according to claim 1, wherein the alcohol-based solvent comprises 2-propanol.

8. The cleaning composition of claim 7, wherein the alcohol-based solvent further comprises at least one selected from the group consisting of ethanol, 1-propanol, 1-butanol and 1-pentanol.

9. The cleaning composition of claim 1, wherein a boiling point of the alcohol-based solvent is 110° C. or less, and a vapor pressure of the alcohol-based solvent at 25° C. is 0.5 kPa or higher.

10. The cleaning composition of claim 1, wherein a content of the alcohol-based solvent is 99 wt % or more, and less than 100 wt % based on the total weight of the composition.

11. The cleaning composition of claim 1, wherein the composition satisfies Formula 1: 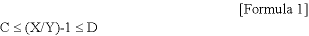
wherein, in Formula 1, X represents a total content of an aldehyde-based compound and a ketone-based compound based on the total weight of the composition, measured after a storage of the composition at 60° C. for 90 days,
Y represents a total content of the aldehyde-based compound and the ketone-based compound based on the total weight of the composition, measured before the storage, and
C is greater than 0 and 0.05 or less, and D is in a range from 0.07 and 0.2.

12. A method of forming a photoresist pattern, the method comprising:
forming a photoresist layer on a substrate;
partially removing the photoresist layer to form a photoresist pattern; and
cleaning the substrate on which the photoresist pattern is formed using the cleaning composition of claim 1.

13. The method of claim 12, further comprising washing the substrate on which the photoresist pattern is formed with water prior to the cleaning using the cleaning composition.
